(19) United States
(12) Patent Application Publication
(10) Pub. No.: US 2012/0192919 A1
(43) Pub. Date: Aug. 2, 2012

(54) FRESNEL-FLY'S EYE MICROLENS ARRAYS FOR CONCENTRATING SOLAR CELL

(75) Inventor: Yosuke MIZUYAMA, Newton, MA (US)

(73) Assignee: Panasonic Corporation, Osaka (JP)

(21) Appl. No.: 13/444,923

(22) Filed: Apr. 12, 2012

Related U.S. Application Data
(63) Continuation of application No. PCT/JP2011/073760, filed on Oct. 7, 2011.
(60) Provisional application No. 61/418,545, filed on Dec. 1, 2010.

(51) Int. Cl. H01L 31/052; H01L 31/0232; B29D 11/00; G02B 3/08

(52) U.S. Cl. 136/246; 359/742; 136/259; 264/1.7

(57) ABSTRACT

Optical elements, concentrating photovoltaic devices and methods of forming optical elements are provided. An optical element includes a transparent material including a first surface and a second surface opposite the first surface. The first surface has a Fresnel lens and the second surface has a plurality of microlenses corresponding to the Fresnel lens. One of the first surface and the second surface is configured to receive light. The optical element is configured so that light passing through the optical element is separated into a plurality of beamlets via the plurality of microlenses. The Fresnel lens has a height where, at the height of the Fresnel lens, a diffraction efficiency of at least two different wavelengths of the light passing through the optical element is maximized.

### CROSS REFERENCE TO RELATED APPLICATIONS

This is a continuation application of International Application No. PCT/JP2011/073760, with an international filing date of Oct. 7, 2011, which claims priority of U.S. Provisional Application No. 61/418,545 entitled FRESNEL-FLY'S EYE MICROLENS ARRAYS FOR CONCENTRATING SOLAR CELL filed on Dec. 1, 2010, the contents of which are incorporated herein by reference.

### TECHNICAL FIELD

The present invention relates to concentrating photovoltaic (PV) devices and, more particularly, to concentrating optics for PV cells having a Fresnel lens and a microlens array optimized to provide low dispersion and homogenization for two or more wavelengths of light.

### BACKGROUND ART

Photovoltaic (PV) cells (e.g., solar cells) are devices which convert light (e.g., solar radiation) into electronic energy. In general, PV cells are formed of one or more light absorbing materials selected to match the spectrum of the light. Multi-junction PV cells may be formed with multiple materials, where each material is configured to absorb a different wavelength band of light, so that nearly all of the solar spectrum may be absorbed. For example, a conventional triple-junction photovoltaic cell may include three wavelength bands with center wavelengths at around 0.5 μm, 0.8 μm and 1.3 μm, and may cover a large region of the solar spectrum (e.g., from about 300 nm to about 1600 nm). Because triple-junction PV cells may be expensive to manufacture, it is desirable to operate them with as much concentration of solar radiation as possible.

Concentrating optics are known to be used with PV cells for the collection and concentration of light. Concentrating optics may increase the energy conversion efficiency of PV cells. Improvements in concentrating optics are needed to achieve high efficiency and compact light concentration systems with low dispersion over the solar spectrum.

### SUMMARY OF THE INVENTION

The present invention relates to an optical element. The optical element includes a transparent material including a first surface and a second surface opposite the first surface. The first surface has a Fresnel lens and the second surface has a plurality of microlenses corresponding to the Fresnel lens. One of the first surface and the second surface is configured to receive light. The optical element is configured so that light passing through the optical element is separated into a plurality of beamlets via the plurality of microlenses. The Fresnel lens has a height where, at the height of the Fresnel lens, a diffraction efficiency of at least two different wavelengths of the light passing through the optical element is maximized.

The present invention also relates to a concentrating photovoltaic (PV) device. The concentrating PV device includes at least one concentrating lens configured to receive light and to separate the light passing through the respective concentrating lens into a plurality of beamlets. Each concentrating lens includes a first surface having a Fresnel lens and a second surface opposite the first surface. The second surface has a plurality of microlenses. The Fresnel lens has a height where, at the height of the Fresnel lens, a diffraction efficiency of at least two different wavelengths of the light passing through the concentrating lens is maximized. The concentrating PV device also includes at least one PV cell corresponding to the at least one concentrating lens configured to receive the respective plurality of beamlets.

The present invention further relates to methods of forming an optical element. The method includes selecting at least two different wavelengths within a wavelength band; determining a Fresnel lens height to maximize a diffraction efficiency of the selected different wavelengths; and forming, on a surface of a transparent material, at least one Fresnel lens with the Fresnel lens height.

### BRIEF DESCRIPTION OF THE DRAWINGS

The invention may be understood from the following detailed description when read in connection with the accompanying drawing. It is emphasized, according to common practice, that various features of the drawing may not be drawn to scale. On the contrary, the dimensions of the various features may be arbitrarily expanded or reduced for clarity. Moreover, in the drawing, common numerical references are used to represent like features. Included in the drawing are the following figures:

FIG. 1 is an example radiance spectrum as a function of wavelength of solar radiation;

FIG. 2 is a cross-section diagram of a concentrating PV device according to an exemplary embodiment of the present invention;

FIG. 3A is a top-plan view diagram of a concentrating lens used in the concentrating PV device shown in FIG. 2, according to an exemplary embodiment of the present invention;

FIG. 3B is a bottom-plan view diagram of the concentrating lens shown in FIG. 3A, according to an exemplary embodiment of the present invention;

FIG. 3C is a cross-section diagram of the concentrating lens shown in FIG. 3A, according to an exemplary embodiment of the present invention;

FIG. 3D is a cross-section diagram of a portion of the concentrating lens shown in FIG. 3C, illustrating a height of a Fresnel lens included in the concentrating lens, according to an exemplary embodiment of the present invention;

FIG. 4 is a cross-section diagram of a concentrating PV device, according to another exemplary embodiment of the present invention;

FIG. 5 is a flow chart diagram illustrating a method of forming a optical element, according to an exemplary embodiment of the present invention;

FIG. 6 is an example phase retardation as a function of Fresnel lens height for various wavelengths of solar radiation;

FIG. 7 is an example square error sum phase retardation as a function of Fresnel lens height for the combination of three wavelengths of solar radiation shown in FIG. 6, according to an exemplary embodiment of the present invention;

FIG. 8 is an example diffraction efficiency as a function of wavelength for Fresnel lens heights that optimize a diffraction efficiency and for a non-optimized diffraction efficiency, according to an exemplary embodiment of the present invention;

FIGS. 9A, 9B and 9C are example ray trace diagrams illustrating various wavelengths of light directed by an exemplary concentrating lens to a target area, according to an embodiment of the present invention;

FIGS. 9D, 9E, 9F, 9G, 9H and 9I are example spot diagrams illustrating a distribution on the target area of the various wavelengths of light shown in respective FIGS. 9A, 98 and 9C, according to an embodiment of the present invention;

FIGS. 10A, 108 and 10C are example graphs of irradiation contour as a function of coordinate value on the target area for the various wavelengths of light shown in respective FIGS. 9A, 98 and 9C, according to an embodiment of the present invention;

FIGS. 10D, 10E and 10F are example cross-section diagrams in two-dimensions of the irradiation contour shown in respective FIGS. 10A, 10B and 10C, according to an embodiment of the present invention;

FIG. 11A is a top-plan view diagram of a concentrating PV device, according to another exemplary embodiment of the present invention;

FIG. 11B is a bottom-plan view diagram of the concentrating PV device shown in FIG. 11A, according to an exemplary embodiment of the present invention;

FIG. 11C is a cross-section diagram of the concentrating PV device shown in FIG. 11A, according to an exemplary embodiment of the present invention; and

FIG. 12 is an example ray trace diagram illustrating multiple wavelengths of light directed by an exemplary concentrating lens to a target area, according to an embodiment of the present invention.

### DESCRIPTION OF EMBODIMENTS

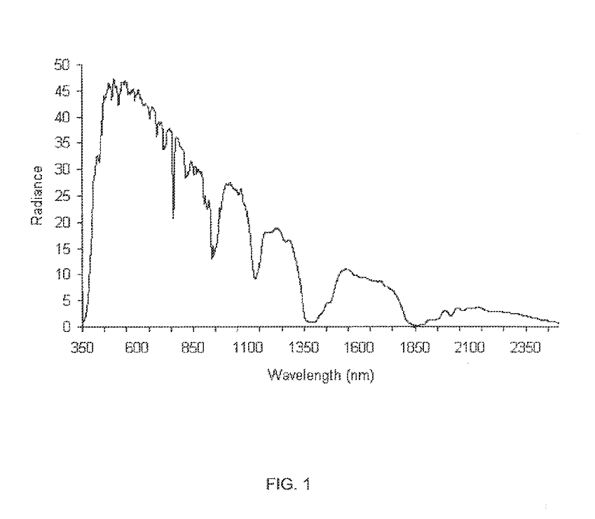

As shown in FIG. 1, the solar spectrum spans a large range of wavelengths, from visible light to infrared light (for example from about 350 nm to about 2350 nm). As discussed above, conventional multi-junction PV cells are designed to convert a large portion of the solar spectrum into electrical energy. Multi-junction PV cells may be used together with conventional concentrating optics, to improve the conversion efficiency of the PV cells. However, conventional optics (such as refractive optics, reflective optics and diffractive optics) are typically optimized for monochromatic light (i.e., a single wavelength). For a small range of wavelengths near this single wavelength, conventional concentrating optics may still operate without severe aberration. For a large range of wavelengths (such as the solar spectrum), however, conventional concentrating optics may suffer from dispersion (i.e., where different wavelengths have different focal lengths).

For example, conventional diffractive optics typically have a negative dispersion, where shorter wavelengths focus to a longer focal point and longer wavelengths focus to a shorter focal point (for example, red light may diffract more than blue light). Conventional refractive optics typically have a positive dispersion, where longer wavelengths focus to a longer focal point and shorter wavelengths focus to a shorter focal point (for example, blue light may diffract more than red light). Dispersion by diffractive optics may be a more serious problem than dispersion by refractive optics, because the optical power provided by conventional diffractive optics is typically larger than refractive optics by an order of about 10.

As shown in FIG. 1, solar radiation has a non-uniform irradiance over the spectrum. To improve the opto-electrical conversion efficiency of the PV cell, it is typically desired to provide a uniform irradiance (i.e., homogenization) on the PV cell. However, conventional concentrating optics, such as conventional Fresnel lenses, may not provide homogenization for all wavelengths of the solar spectrum.

One conventional method of light homogenization is a fly's eye system including a fly's eye lens array and a field lens. In the conventional fly's eye system, each microlens of the array focuses a collimated beamlet onto a surface of the field lens. The field lens recollimates the beamlets, such that the recollimated beamlets are superimposed on an image plane. In this manner, an averaged and homogenized light distribution may be obtained. However, because solar radiation is incoherent light, conventional fly's eye systems may not be suitable for concentrating PV devices, due to the required distance between the array and the field lens. For example, for incoherent light, the distance between the fly's eye lens array and the field lens tends to be long (about 20 mm in length). Thus, it may be difficult to form compact concentrating PV cells with a conventional fly's eye system.

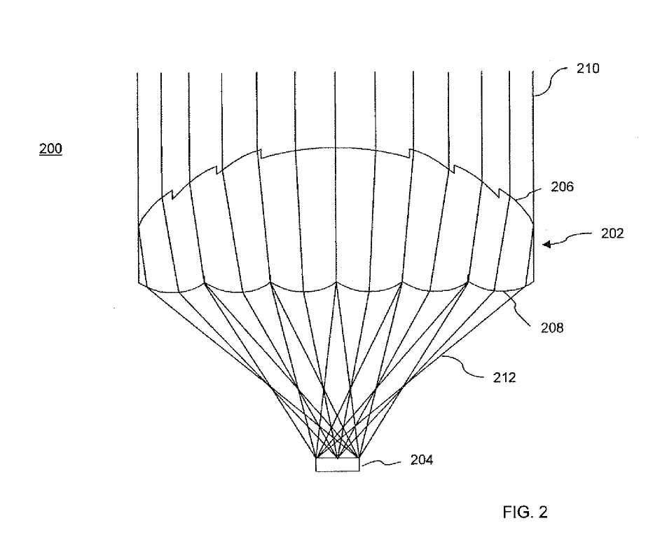

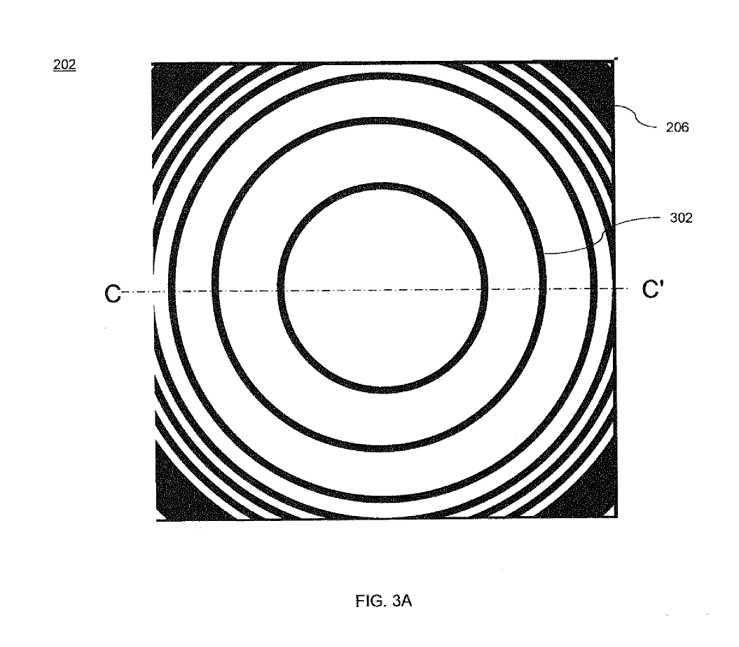

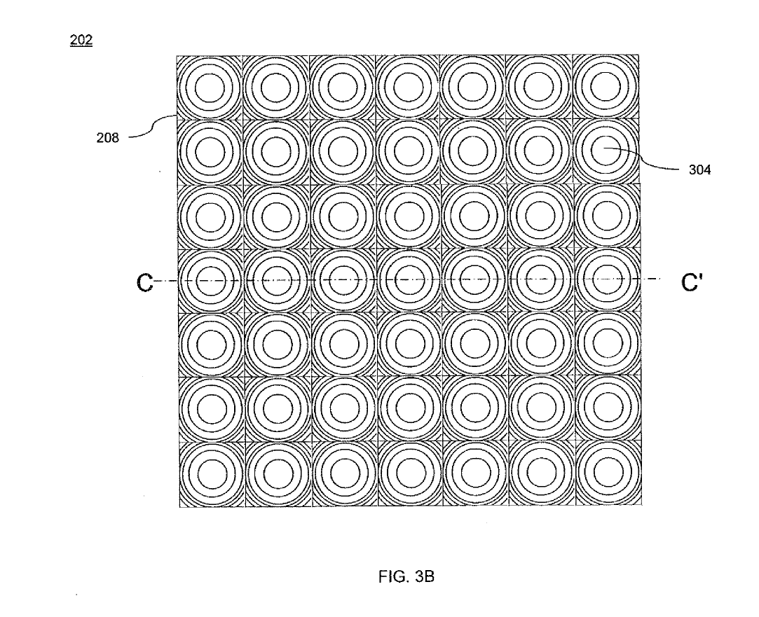

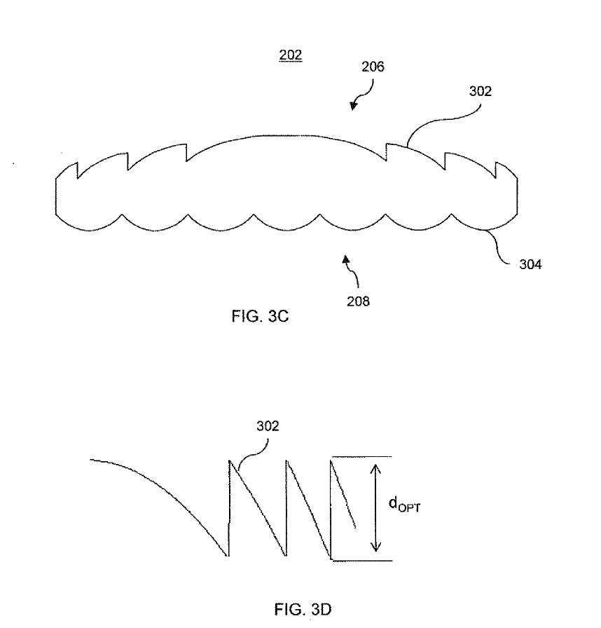

Referring to FIG. 2, a cross-section diagram is shown of exemplary concentrating PV device 200 (also referred to herein as device 200), according to an embodiment of the present invention. Device 200 may include concentrating lens 202 and PV cell 204 (spaced apart from concentrating lens 202). PV cell 204 may include any suitable PV cell, including single-junction and multi-junction type PV cells, capable of converting at least a portion of the solar spectrum of light 210 into electrical energy. As described further below with respect to FIGS. 3A-3D, concentrating lens 202 may be configured to provide homogenization, focusing and low dispersion for multiple wavelengths of light within the solar spectrum.

In operation, light 210 (for example, solar radiation having a solar spectrum) is received by first surface 206 of concentrating lens 202 and split into plurality of beamlets 212 via second surface 208. Concentrating lens 202 may be configured to superimpose beamlets 212 onto PV cell 204. PV cell 204 may convert the superimposed beamlets 212 into electrical energy.

Referring next to FIGS. 2 and 3A-3D, concentrating lens 202 is further described. In particular, FIG. 3A is a top-plan view diagram of concentrating lens 202 illustrating first surface 206; FIG. 3B is a bottom-plan view diagram of concentrating lens 202 illustrating second surface 208; FIG. 3C is a cross-section diagram of concentrating lens 202; and FIG. 3D is a cross-section diagram of a portion of first surface 206 illustrating optimized Fresnel lens height (d_{OPT}) of Fresnel lens 302.

First surface 206 of concentrating lens 202 may include a curvature (either aspheric or spherical), such that light 210 may be refracted and focused onto PV cell 204. Accordingly, the curvature of first surface 206 (i.e., a refractive surface) acts similar to a field lens used in a fly's eye system. Second surface 208 may include a plurality of microlenses 304, arranged as a fly's eye lens array, configured to split light 210 into a plurality of beamlets 212 corresponding to the number of microlenses 304. Beamlets 212 are superimposed (via the curvature of first surface 206) onto PV cell 204.

In general, each microlens 304 is a small refractive lens (for example, with a diameter of less than about 1.5 mm), such that the diameter of each microlens 304 is less than a diameter of concentrating lens 202. A convex surface of each microlens 304 may be spherical or aspherical. Examples of microlenses are described in U.S. Pat. No. 6,741,394, incorporated herein by reference.

Microlenses 304 are configured to provide light homogenization. Beamlets 212 may be focused (by first surface 206) at a position between second surface 208 and PV cell 204 (i.e., in front of PV cell 204), such that inverted images from beamlets 212 may be superimposed on PV cell 204. Because each beamlet 212 is focused in front of PV cell 204, each beamlet 212 diverges, to produce an extended area rather than a focused spot on the surface of PV cell 204. Beamlets 212 are superimposed at approximately a same position on PV cell 204 to produce a predetermined size of homogenized irradiation, so that the overall image (on PV cell 204) becomes an averaged and homogenized illumination (i.e., a uniform intensity distribution).

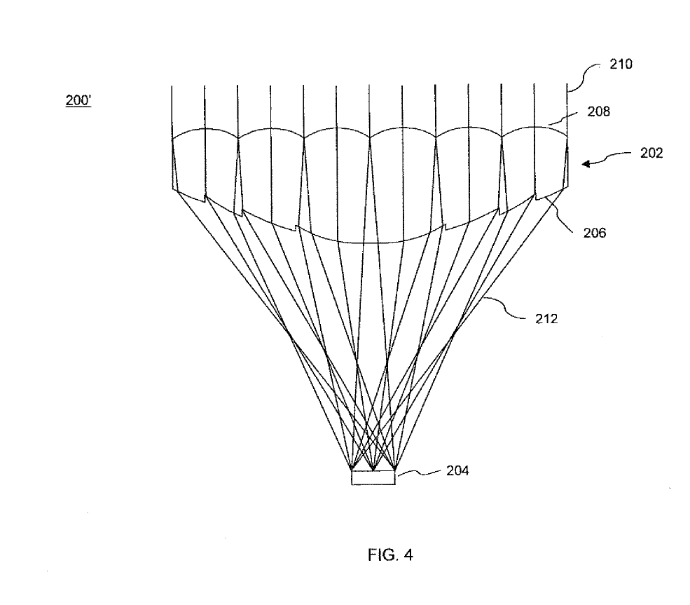

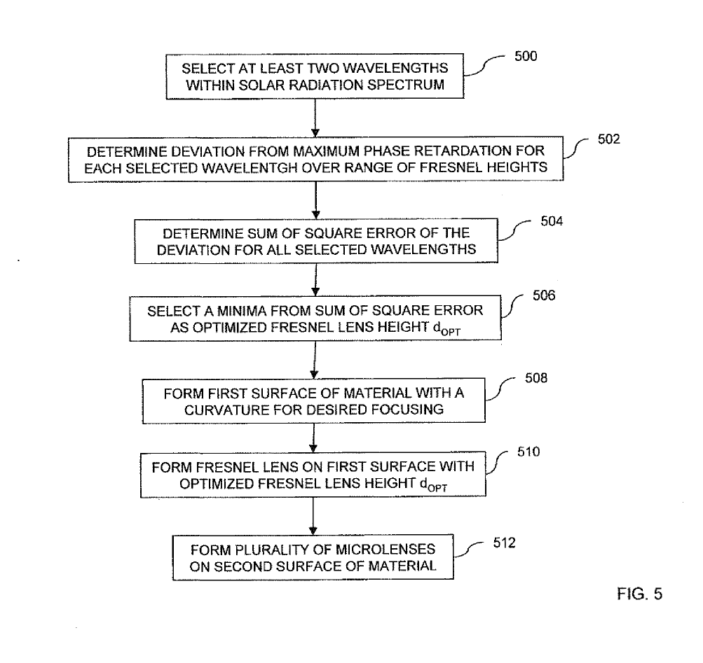

First surface 206 also includes Fresnel lens 302. Fresnel lens 302 is a diffractive optic configured with Fresnel lens height d_{OPT} to cancel chromatic dispersion from at least two wavelengths of light within the solar spectrum. As described further below with respect to FIG. 5, the Fresnel lens height d_{OPT} is determined to maximize a diffraction efficiency of at least two different wavelengths of light within the solar spectrum. Thus, the Fresnel lens height d_{OPT} may be selected to compensate chromatic dispersion over a wide range of the solar spectrum.

Because first surface 206 includes a curvature, first surface 206 (and microlenses 304) acts as a refractive lens and may include a positive dispersion. In contrast, Fresnel lens 302 (a diffractive optic) includes a negative dispersion. A small amount of the optical phase with Fresnel lens 302 may compensate positive dispersion from (curved) first surface 206, as well as any aspheric surfaces of microlenses 304 (on second surface 208).

The dispersion of diffractive optics may be explained based on the grating equation:

p sin(θ)=mλ (1)

where p, θ, m and λ represent the grating period, the diffraction angle, the diffraction order and the wavelength, respectively. As shown in eq. (1), the diffraction angle θ is approximately proportional to the wavelength λ. This linear relation between diffraction angle and wavelength may produce a large dispersion.

In contrast, the refractive angle for refractive lenses (such as first surface 206) is determined by Snell's law. A wavelength dependence on the refraction angle is determined by the lens material dispersion (i.e., the refractive index as a function of wavelength), which is typically a slowly varying function. Accordingly, for refractive lenses, changes in the wavelength may produce only a small difference in the refractive angle. Thus, a small amount of the optical phase with Fresnel lens 302 may compensate positive dispersion from a refractive surface. However, the Fresnel lens height d_{OPT} is selected in order to obtain a high diffraction efficiency for selected wavelengths over the solar spectrum.

Concentrating lens 202 may be formed of a transparent material having a refractive index (n). Transparent, as used herein, means having substantial optical transmission at those wavelengths within the spectrum of solar radiation. Concentrating lens 202 may be formed from any suitable transparent material, such as quartz, BK7, sapphire and other optical grade glass, and transparent plastic materials, such as acrylic and polycarbonate. For example, ZEONEX® (manufactured by ZEON Chemical) is a plastic material suitable for ultraviolet (UV) and UV-blue wavelengths in terms of durability.

Concentrating lens 202 may include any suitable number of microlenses 304 for homogenization. According to an exemplary embodiment, the number of microlenses 304 may include between about 10 to about 100 per row (to form respective arrays of between about 10×10 microlenses 304 to about 100×100 microlenses 304). A diameter of microlenses 304 may include any suitable diameter for forming beamlets 212. According to an exemplary embodiment, a diameter of microlenses 304 may range between about 0.15 mm to about 1.5 mm. A total thickness of concentrating lens 202 (i.e., between first surface 206 and second surface 208) may include any suitable thickness. According to an exemplary embodiment, the thickness of concentrating lens 202 may include between about 1 mm to about 10 mm. The curvature of first surface 206 may include any suitable curvature to provide focusing onto PV cell 204. It is understood that the curvature of first surface 206, Fresnel lens 302 and microlenses 304 may be configured to take into account the divergence and convergence angles of incident light 210 (typically about 0.3°).

Although FIG. 2 illustrates concentrating lens 202 configured with first surface 206 positioned to receive light 210, concentrating lens 202 is not limited to this configuration. Referring to FIG. 4, a cross-section diagram of concentrating PV device 200′ is shown, according to another exemplary embodiment of the present invention. Device 200′ is similar to device 200 (FIG. 2), except that concentrating lens 202 is positioned to receive light 210 at second surface 208 and to provide beamlets 212 (via microlenses 304) from first surface 206. First surface 206 may include a curvature so that beamlets 212 converge and are superimposed on PV cell 204.

Referring next to FIG. 5, an exemplary method of forming an optical element (such as concentrating lens 202 (FIG. 2) is shown. The steps illustrated in FIG. 5 represent an example embodiment of the present invention. It is understood that certain steps may be performed in an order different from what is shown.

At step 500, at least two wavelengths of light within the solar spectrum are selected. The selected wavelengths may be determined, for example, based on atmospheric absorption of solar radiation (i.e., as shown in FIG. 1) and/or the wavelength band (or bands) of light capable of being absorbed and converted into electrical energy by PV cell 204 (FIG. 2). For example, if PV cell 204 (FIG. 2) is a triple-junction PV cell, three wavelengths (for example, 0.5 μm, 0.8 μm and 1.3 μm) may be selected to correspond with the wavelength bands absorbed by the triple-junction PV cell.

At steps 502-506, a diffraction efficiency is determined which is maximized for the selected wavelengths.

For individual wavelengths, the diffraction efficiency may be maximized when the phase retardation (φ) is 2π (i.e., a maximum phase retardation). The phase retardation φ, for a non-optimized Fresnel lens height (d) and an m^{th} order of diffraction at wavelength λ is given as:

$$φ ( d , λ ) = \frac{2 π d ( n ( λ ) - 1 )}{m λ} \qquad ( 2 )$$

The phase retardation φ represents the unwrapped phase retardation. The wrapped phase retardation (φ_{F}) (i.e., folded into the range of 2π) is given by:

$${φ}_{F } ( d , λ ) = mod ( \frac{2 π d ( n ( λ ) - 1 )}{m λ} , 2 π ) \qquad ( 3 )$$

where mod(*) represents the modulus (i.e., a function that extracts the remainder).

Referring to FIG. 6, examples of phase retardation (in radians) as a function of non-optimized Fresnel lens height d are shown for wavelengths 602, 604 and 606. In this example, the Fresnel lens is made of ZEONEX® and wavelengths 602, 604 and 606 respectively represent selected wavelengths 0.5 μm, 0.8 μm and 1.3 μm. In general, the diffraction efficiency of a conventional Fresnel lens is maximized when the phase retardation φ (or φ_{F}) is an integral multiple of 2π (in eq. (2)) (or either 0 or 2π in eq. (3)). As shown in FIG. 6, for a single wavelength (for example, wavelength 602) there are multiple non-optimized Fresnel lens heights d which provide maximum diffraction efficiency. However, the non-optimized Fresnel lens height that maximizes the diffraction efficiency for wavelength 602 is different from the non-optimized Fresnel lens height that maximizes the diffraction efficiency for each of wavelengths 604 and 606. Thus, selection of a non-optimized Fresnel lens height for one of wavelengths 602, 604, 606 may not provide maximum diffraction efficiency for all selected wavelengths 602, 604, 606.

Referring back to FIG. 5, at step 502, a deviation from a maximum phase retardation is determined for each selected wavelength over a range of Fresnel lens heights. At step 504, a sum of the square error of the deviation (step 502) is determined for all of the selected wavelengths. The sum of the square error, referred to herein as the square error (SE) function is given as:

$$SE ( d ) = {\sum }_{i = 1}^{N} {( min ( {φ}_{F} ( d , {λ}_{i} ) , 2 π - {φ}_{F} ( d , {λ}_{i} ) ) )}^{2} \qquad ( 4 )$$

where N represents the number of selected wavelengths and the function MIN (A, B) is represented as:

$$min ( a , b ) = \{ \begin{matrix}a , & a \leq b \\ b , & a > b\end{matrix} \qquad ( 5 )$$

In eq. (4), the term (2π−φ_{F}(d,λᵢ)) represents the deviation from the maximum phase retardation for each selected wavelength λᵢ (step 502) and the term

$${\sum }_{i = 1}^{N} {( min ( A , B ) )}^{2}$$

represents the sum of square error of the deviation for all of the selected wavelengths (step 504). At step 506, a minima is selected from the SE function (step 504) as the optimized Fresnel lens height d_{OPT}.

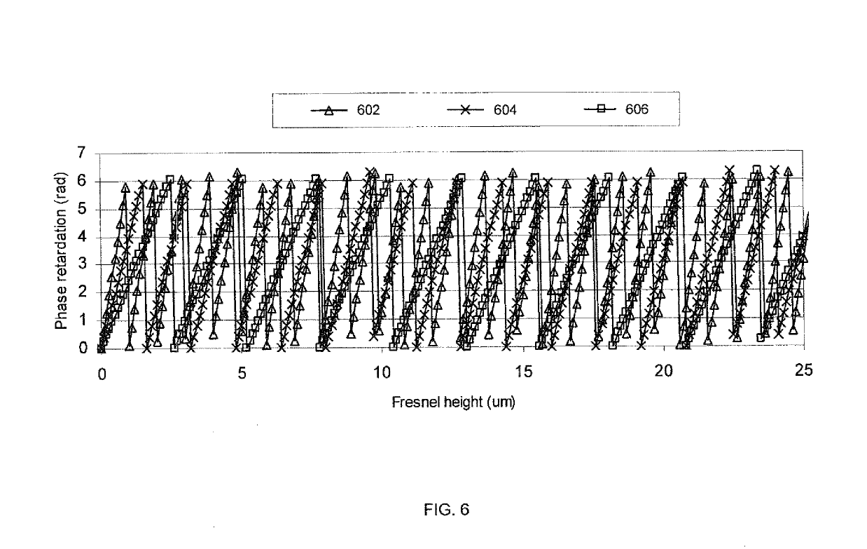

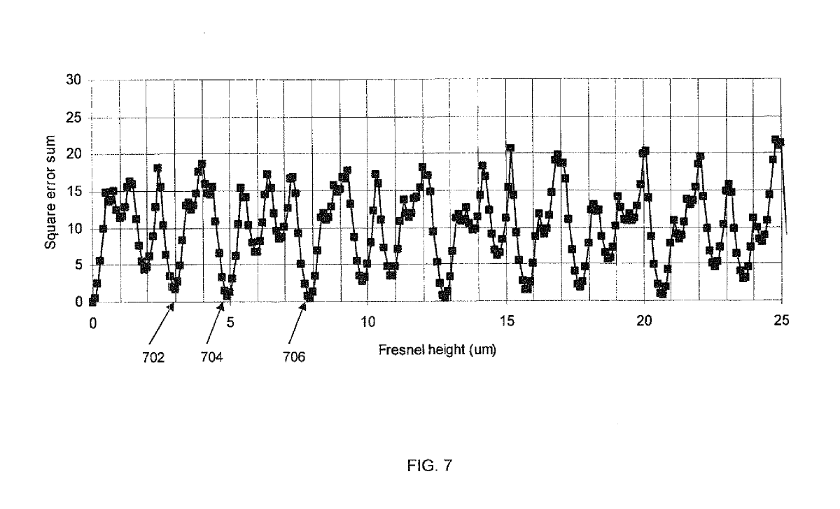

The inventor found that he obtained surprising results when any of the minima from the SE function were selected as the optimized Fresnel lens height d_{OPT}. Namely, a Fresnel lens with d_{OPT} had a high diffraction efficiency for all of the selected wavelengths of the solar spectrum. In contrast, if a Fresnel lens height was selected without considering the phase retardation for all of the selected wavelengths, the Fresnel lens had a low diffraction efficiency. Referring to FIG. 7, an example SE function as a function of Fresnel lens height is shown. In FIG. 7, the example Fresnel lens is made of ZEONEX® and the selected wavelengths are those of FIG. 6 (0.5 μm, 0.8 μm and 1.3 μm). As shown in FIG. 7, the SE function includes a plurality of local minima and a global minimum. Each of these minima represent a minimum mean square deviation from the maximum phase retardation (i.e., 2π) for all of the selected wavelengths. For example, local minima 702 and 704 represent Fresnel lens heights of 3.0 μm and 4.9 μm, respectively. Global minimum 706 represents a Fresnel lens height of 7.9 μm.

Accordingly, any of the minima of the SE function may be selected to maximize the diffraction efficiency of all of the selected wavelengths. The diffraction efficiency (DE) of the highest diffraction order for a Fresnel lens as a function of wavelength may be represented as:

$$DE ( d , λ ) = sin {c}^{2} π ( \frac{d ( n ( λ ) - 1 )}{λ} - m ) . \qquad ( 6 )$$

The diffraction efficiency (DE) in eq. (6) may be used to select an optimized Fresnel lens height d_{OPT} (among the minima of the SE function (eq. (4)), that provides a suitable diffraction efficiency for all of the selected wavelengths while maintaining a practical Fresnel lens height.

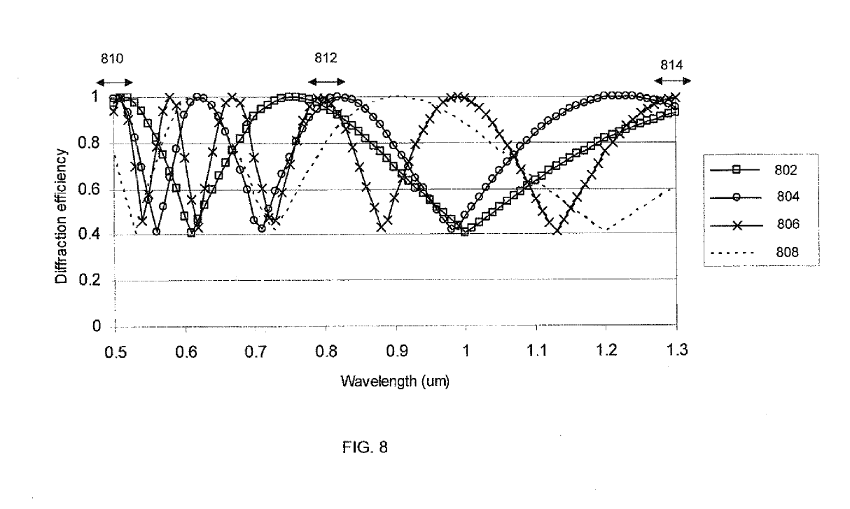

Referring to FIG. 8, example diffraction efficiencies (using eq. (6)) are shown for optimized Fresnel lens heights (curves 802, 804, 806) and a non-optimized Fresnel lens height (curve 808). Curves 802, 804 and 806 represent respective optimized Fresnel lens heights of 3.0 μm, 4.9 μm and 7.9 μm (as determined above with respect to FIG. 7). Curve 808 represents a non-optimized Fresnel lens height of 3.6 μm. Regions 810, 812 and 814 (associated with respective selected wavelengths 0.5 μm, 0.8 μm and 1.3 μm) show that curves 802, 804 and 806 (for the optimized Fresnel lens heights) provide high diffraction efficiencies as compared with curve 808 (for the non-optimized Fresnel lens height). Table 1, shown below, further summarizes the diffraction efficiency (DE), the diffraction order (Order) and optimized Fresnel lens heights for the example three selected wavelengths.

TABLE 1

| Fresnel lens | | | | | | |
|---|---|---|---|---|---|---|
| height | λ = 0.5 μm | | λ = 0.8 μm | | λ = 1.3 μm | |
| (μm) | Order | DE | Order | DE | Order | DE |
| 3 | 3^{rd} | 0.97 | 2^{nd} | 0.96 | 1^{st} | 0.93 |
| 4.9 | 5^{th} | 0.99 | 3^{rd} | 0.98 | 2^{nd} | 0.95 |
| 7.9 | 8^{th} | 0.94 | 5^{th} | 1 | 3^{rd} | 1 |
| 3.6 | 4^{th} | 0.75 | 2^{nd} | 0.79 | 1^{st} | 0.6 |

Accordingly, as shown in Table 1, the minima (both the local minima and the global minimum) provide high diffraction efficiencies for multiple specified wavelengths. The high diffraction efficiencies means that most of the diffracted light of the selected wavelengths may be confined to the designed target area, in order to provide uniform illumination on PV cell 204 (FIG. 2).

As shown in Table 1, the global minimum (i.e., 7.9 μm in this example) provides the highest diffraction efficiency. However, it is understood that a local minimum may be selected (i.e., if the global minimum produces an impractical height). For example, if the Fresnel lens height is too large, the Fresnel lens may generate a shadowing effect, which may produce undesired stray light. Furthermore, different minima may provide better diffraction efficiencies for a particular bandwidths. For example, for a Fresnel lens height of 3 μm, the wavelength ranges of 0.5 μm-56 μm, 0.66 μm-0.86 μm and 1.2 μm-1.3 μm produces greater than 80% diffraction efficiency, which may substantially match the effective solar spectrum modified by the absorption band (or bands) of PV cell 204 (FIG. 2).

Referring back to FIG. 5, at step 508, a first surface (for example, first surface 206 shown in FIG. 2) of a transparent material is formed with a curvature for a desired focusing. At step 510, a Fresnel lens is formed on the first surface with the optimized Fresnel lens height d_{OPT} (step 506). For example, Fresnel lens 302 is formed on first surface 206 (FIG. 2). At step 512, a plurality of microlenses are formed on a second surface (for example, second surface 208 shown in FIG. 2) of the material, to form an optical element (such as concentrating lens 202 shown in FIG. 2). For example, microlenses 304 may be formed on second surface 208 (FIG. 2). Steps 508-512, may be performed, for example, by injection molding, glass molding or lithography.

According to another embodiment, an optical element may also be formed which includes a Fresnel lens having an optimized Fresnel lens height d_{OPT}, by performing steps 500-506 and 510, without performing steps 508 and 512. According to a further embodiment, an optical element may also be formed which includes a Fresnel lens having an optimized Fresnel lens height d_{OPT} and a focusing function, by performing steps 500-510, without performing step 512. Although FIG. 5 illustrates selection of the wavelengths based on the solar spectrum, it is understood that FIG. 5 represents an exemplary embodiment, and that the wavelengths may be selected over any suitable wavelength band.

The inventor simulated ray tracing of various wavelengths of light through concentrating lens 202 (FIG. 2) and examined the diffraction efficiency and distribution of the illumination onto a target area (such as PV cell 204). The inventor found that surprising results were obtained. Namely, that concentrating lens 202 included high diffraction efficiencies for all of the selected wavelengths, while providing substantially uniform illumination distribution to a target area, even for slightly convergent light (for example, a convergence angle of 0.3° corresponding to typical solar radiation).

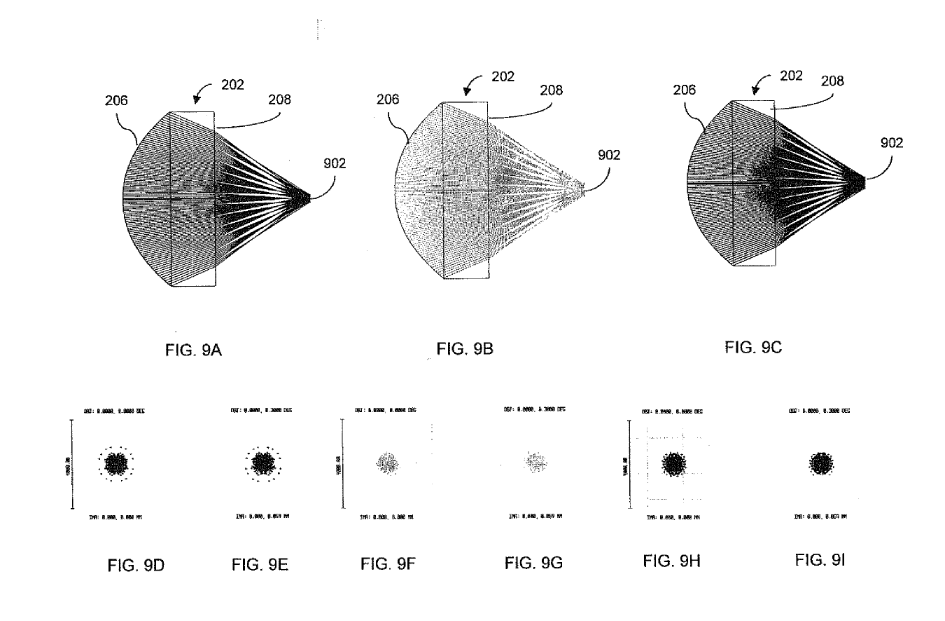

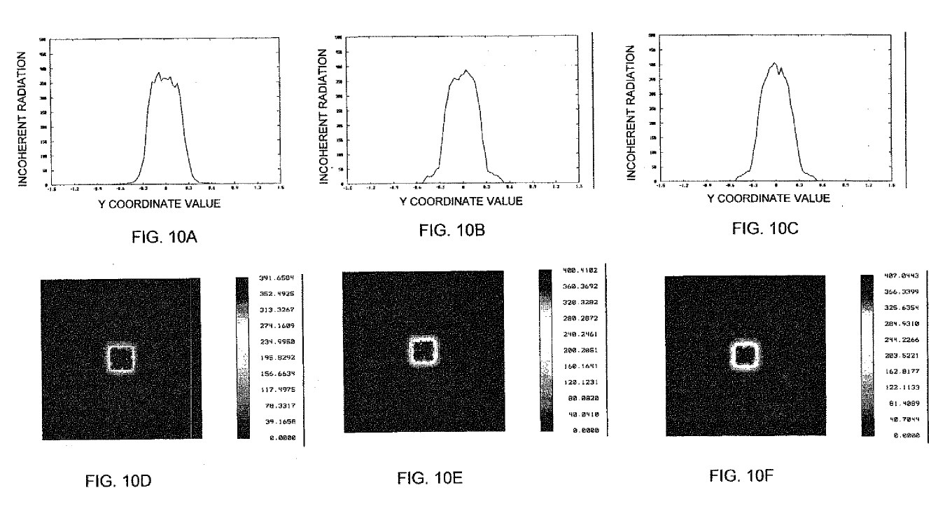

Referring to FIGS. 9A-10F, example ray trace simulation results are illustrated for various wavelengths of light directed to target area 902 via concentrating lens 202. Concentrating lens 202 is arranged as shown in FIG. 2, with first surface 206 configured to receive light and second surface 208 positioned to direct beamlets to target area 902. For convenience, in FIGS. 9A-9C, Fresnel lens 302 (FIG. 3C) on first surface 206 and microlenses 304 (FIG. 3C) on second surface 208 are not shown.

In the example shown in FIGS. 9A-10F, concentrating lens 202 is formed of ZEONEX® and has a diameter of 15 mm. Target area 902 is 0.5 mm by 0.5 mm. Each microlenses 304 (FIG. 3C) on second surface 208 has a diameter of 1 mm, with a total of 15 microlenses 304 in the array. An optimum Fresnel lens height d_{OPT} of 2.9 μm is selected (as described above with respect to FIG. 5), for selected wavelengths of 0.5 μm, 0.8 μm and 1.3 μm. With this selected optimum Fresnel lens height, 5^{th} order, 3^{rd} order and 2^{nd} order diffracted light are dominant for the 0.5 μm, 0.8 μm and 1.3 μm wavelengths, respectively. For d_{OPT} of 2.9 μm, calculated diffraction efficiencies (eq. (6)) are 97%, 89% and 96% for the 0.5 μm, 0.8 μm and 1.3 μm wavelengths, respectively.

FIGS. 9A-9C are example ray trace diagrams for the 0.5 μm, 0.8 μm and 1.3 μm wavelengths, respectively. FIGS. 9D, 9F and 9H are example spot diagrams illustrating a distribution on target area 902 for respective 0.5 μm, 0.8 μm and 1.3 μm wavelengths of perfectly collimated light (i.e., with a divergence angle of 0°). FIGS. 9E, 9G and 9I are example spot diagrams illustrating a distribution on target area 902 for respective 0.5 μm, 0.8 μm and 1.3 μm wavelengths of slightly convergent light (i.e., with a divergence angle of 0.3°, corresponding to solar radiation). FIGS. 9D-9I illustrate the uniformity of the distribution of illumination on target area 902, and that the illumination is confined in target area 902. In FIGS. 9A-91, although the diffraction angle is considered, the irradiation and the diffraction efficiency are not taken into account. The ray tracing results are generated based on geometrical optics.

FIGS. 10A-10C are example graphs of irradiation contour for the 0.5 μm, 0.8 μm and 1.3 μm wavelengths, respectively, when the irradiation is taken into consideration. FIGS. 10D, 10E and 10F are example cross-section diagrams in two-dimensions of the irradiation contour shown in respective FIGS. 10A, 10B and 10C. In FIGS. 10A-10F, the diffraction efficiency is not taken into account. The results shown in FIGS. 10A-10F are generated based on Monte-Carlo methods. FIGS. 10A-10C also illustrate the uniformity of the distribution of illumination on target area 902, and that the illumination is confined in target area 902.

Referring back to FIG. 2, concentrating lens 202 represents a monolithic lens capable of producing uniform illumination on PV cell 204 and minimal color dispersion for multiple selected wavelengths that may be associated with one or more absorption bands of PV cell 204. Concentrating lens 202 may have a reduced production cost and may be formed to be compact, while still providing a focused uniform intensity distribution on PV cell 204.

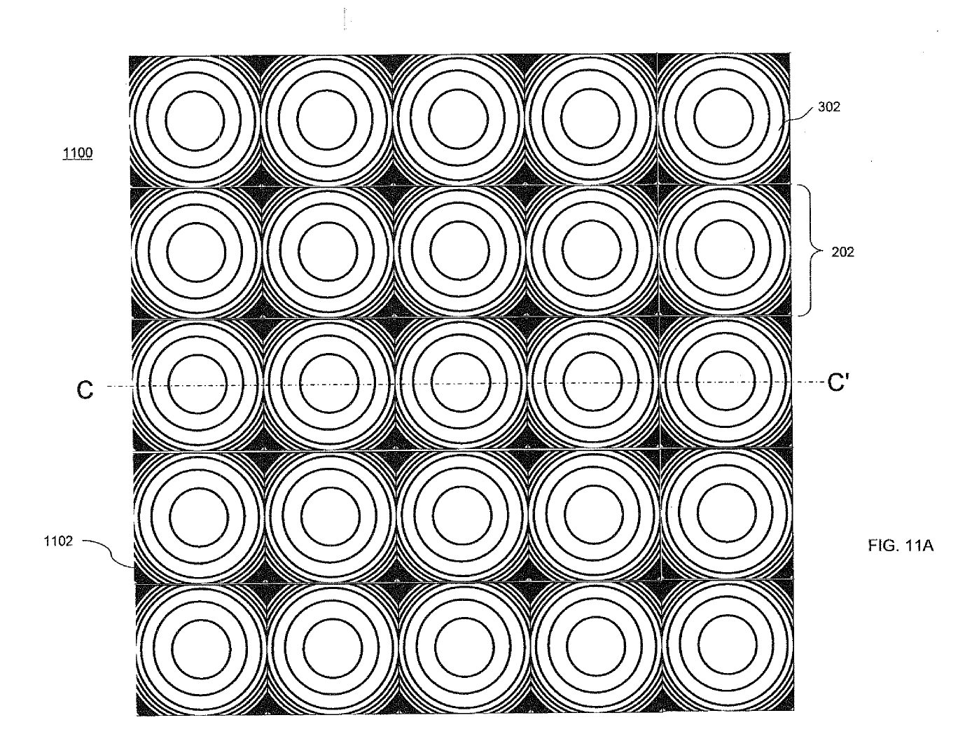

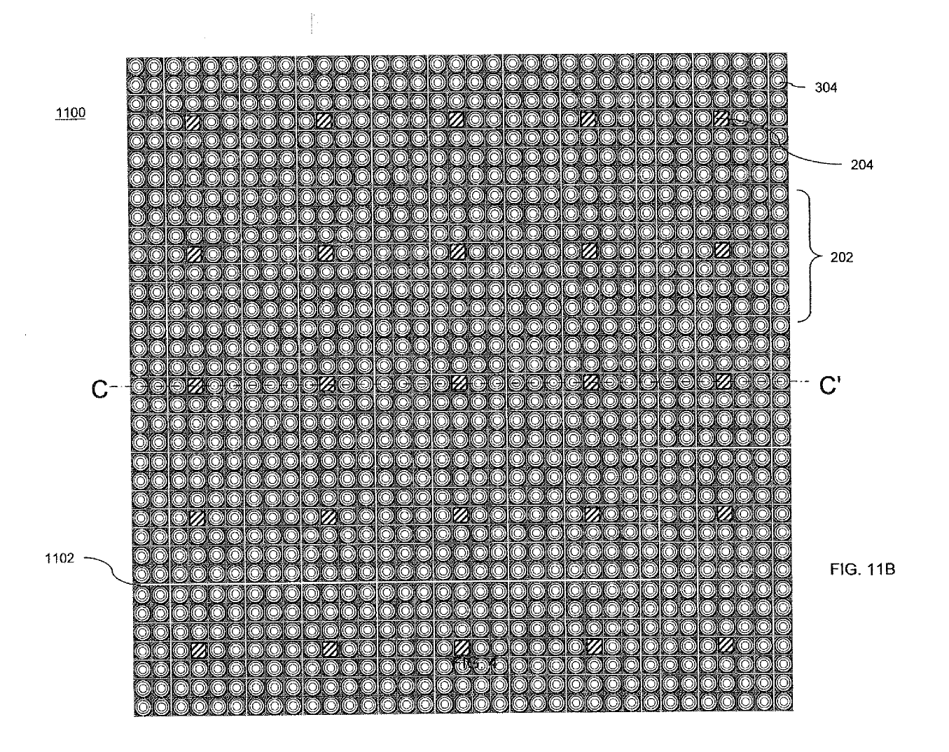

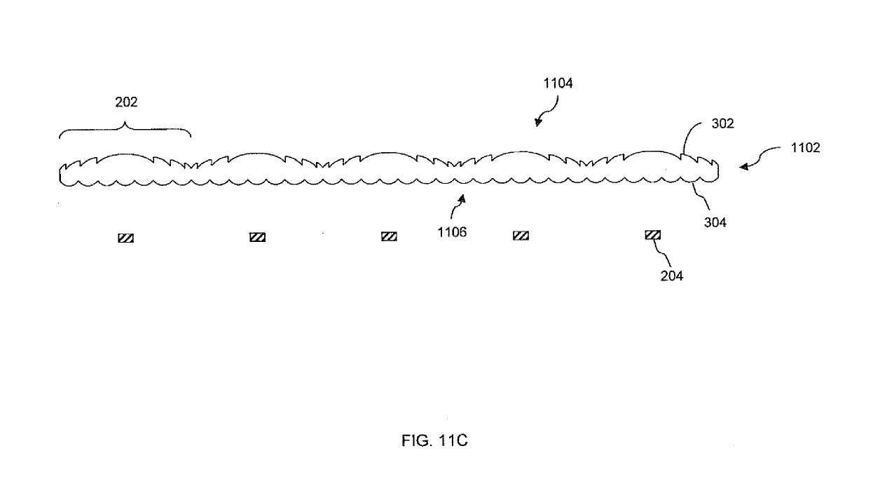

Although FIGS. 2-5 describe a single concentrating lens 202, an array of concentrating lenses 202 may also be formed. Referring next to FIGS. 11A-11C, concentrating PV device 1100 (refer to herein as device 1100) is shown. In particular, FIG. 11A is a top-plan view diagram of device 1100 illustrating first surface 1104 of concentrating lens array 1102 (refer to herein as array 1102); FIG. 11B is a bottom-plan view diagram of device 1100 illustrating second surface 1106 of array 1102 and corresponding PV cells 204; and 11C is a cross-section diagram of device 1100.

Array 1102 includes a plurality of concentrating lenses 202. A PV cell 204 may be associated with a respective concentrating lens 202. Each concentrating lens 202 may include Fresnel lens 302 on first surface 1104 and a plurality of microlenses 304 on a second surface 1106 of array 1102. Array 1102 may be formed as described above with respect to FIG. 5, such that each Fresnel lens 302 has an optimized Fresnel lens height d_{OPT}.

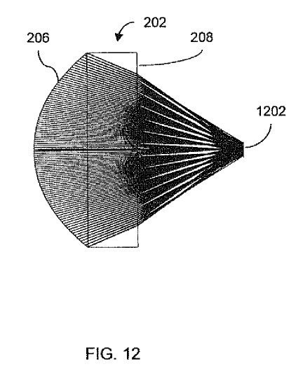

Referring next to FIG. 12, a design example of concentrating lens 202 is described. FIG. 12 is an example ray trace diagram illustrating wavelengths 0.5 μm 0.8 μm and 1.3 μm directed by concentrating lens 202 to target area 1202. Concentrating lens 202 is arranged as shown in FIG. 2, with first surface 206 configured to receive light and second surface 208 positioned to direct beamlets to target area 1202. For convenience, in FIG. 12, Fresnel lens 302 (FIG. 3C) on first surface 206 and microlenses 304 (FIG. 3C) on second surface 208 are not shown.

In the example shown in FIG. 12, concentrating lens 202 is formed of BK7 and has an optimum Fresnel lens height d_{OPT} of 4.9 μm. For d_{OPT} of 4.9 μm, calculated diffraction efficiencies (eq. (6)) are 100%, 99% and 97% for the 0.5 μm, 0.8 μm and 1.3 μm wavelengths, respectively.

The aspherical surface formula (S) as a function of pupil coordinate (r), is shown below in eq. (7).

$$S ( r ) = \frac{{cr}^{2}}{1 + \sqrt{1 - ( 1 + k ) {c}^{2} {r}^{2}}} + {A}_{2} {r}^{2} + {A}_{4} {r}^{4} + {A}_{6} {r}^{6} + {A}_{8} {r}^{8} + {A}_{10} {r}^{10} + {A}_{12} {r}^{12} + {A}_{14} {r}^{14} + {A}_{16} {r}^{16} \qquad ( 7 )$$

In eq. (7), r represents the surface sag of the refractive surface of first surface 206. The surface sag r may be defined as the height of a lens position from a reference point (such as a spherical curve). The term c represents the curvature, which is equal to the reciprocal of the radius of curvature R (i.e., c=1/R). The term k represents a conic constant. The remaining terms in eq. (7) represent higher order polynomial aspheric terms, where A represents the coefficient for each higher order term.

Tables 2A and 2B, shown below, summarize coefficients of eq. (7) for an example design of concentrating lens 202. In Tables 2A and 2B, the first row represents the coefficients of the base curvature of first surface 206. The second row represents the coefficients of the phase function (i.e., phase retardation φ) of Fresnel lens 302 (FIG. 3C) on first surface 206. The relation between phase retardation and Fresnel lens height is described above with respect to eqs. (2) and (3). The third row represents the coefficients of a single microlens 304 (FIG. 3C) on second surface 208. On second surface 208, there is no base curvature, because microlenses 304 are fabricated on a planar surface.

TABLE 2A

| | R (=1/c) | k | A₂ | A₄ | A₆ |
|---|---|---|---|---|---|
| Refractive surface | 9.1474 | 0.2013 | 0 | 1.9504e⁻³ | −2.046e⁻³ |
| function | | | | | |
| Fresnel lens phase | 0 | 0 | −10.3879 | 0.0732 | −1.531e⁻³ |
| function | | | | | |
| microlens | −10 | −1 | 0 | 0 | 0 |
| function | | | | | |

TABLE 2B

| | A₈ | A₁₀ | A₁₂ | A₁₄ | A₁₆ |
|---|---|---|---|---|---|
| Refractive surface function | 1.129e⁻⁵ | −3.516e⁻⁷ | 6.1125e⁻⁹ | −5.578e⁻¹¹ | 2.074e⁻¹³ |
| Fresnel lens phase function | 0 | 0 | 0 | 0 | 0 |
| microlens function | 0 | 0 | 0 | 0 | 0 |

Although the invention is illustrated and described herein with reference to specific embodiments, the invention is not intended to be limited to the details shown. Rather, various modifications may be made in the details within the scope and range of equivalents of the claims and without departing from the invention.

1. An optical element comprising:
a transparent material including a first surface having a Fresnel lens and a second surface opposite the first surface, the second surface having a plurality of microlenses corresponding to the Fresnel lens,
one of the first surface and the second surface is configured to receive light, the optical element being configured so that light passing through the optical element is separated into a plurality of beamlets via the plurality of microlenses, and
the Fresnel lens has a height, wherein at the height of the Fresnel lens, a diffraction efficiency of at least two different wavelengths of the light passing through the optical element is maximized.

2. The optical element according to claim 1, wherein the height of the Fresnel lens is configured to simultaneously minimize an error in deviation from a maximum phase retardation for the at least two different wavelengths.

3. The optical element according to claim 1, wherein the Fresnel lens is configured to compensate for a dispersion by at least one of the first surface or the second surface.

4. The optical element according to claim 1, wherein the light includes solar radiation.

5. The optical element according to claim 1, wherein the Fresnel lens includes a plurality of Fresnel lenses.

6. The optical element according to claim 1, wherein the first surface includes a refractive surface.

7. The optical element according to claim 6, wherein the refractive surface is configured to superimpose the plurality of beamlets at a predetermined position.

8. The optical element according to claim 7, wherein the plurality of microlenses are configured to produce a homogenized light distribution at the predetermined position.

9. A concentrating photovoltaic (PV) device comprising:
at least one concentrating lens configured to receive light and to separate the light passing through the respective concentrating lens into a plurality of beamlets, each concentrating lens comprising:
a first surface having a Fresnel lens and a second surface opposite the first surface, the second surface having a plurality of microlenses,
the Fresnel lens having a height, wherein at the height of the Fresnel lens a diffraction efficiency of at least two different wavelengths of the light passing through the concentrating lens is maximized; and
at least one PV cell corresponding to the at least one concentrating lens configured to receive the respective plurality of beamlets.

10. The concentrating PV device according to claim 9, wherein, for each concentrating lens, the height of the Fresnel lens is configured to simultaneously minimize an error in deviation from a maximum phase retardation for the at least two different wavelengths.

11. The concentrating PV device according to claim 9, wherein, for each concentrating lens, the at least two different wavelengths correspond to one or more wavelength absorption bands of the corresponding PV cell.

12. The concentrating PV device according to claim 9, wherein each concentrating lens is configured to receive the light via the first surface.

13. The concentrating PV device according to claim 9, wherein each concentrating lens is configured to receive the light via the second surface.

14. The concentrating PV device according to claim 9, wherein the at least one concentrating lens includes a plurality of concentrating lens and the at least one PV cell includes a plurality of PV cells.

15. The concentrating PV device according to claim 9, wherein, for each concentrating lens, the Fresnel lens is configured to compensate for a dispersion by at least one of the first surface or the second surface.

16. The concentrating PV device according to claim 9, wherein, for each concentrating lens, the first surface is configured to superimpose the respective plurality of beamlets onto the corresponding PV cell.

17. The concentrating PV device according to claim 16, wherein, for each concentrating lens, the first surface is configured to focus the respective plurality of beamlets to a position between the concentrating lens and the corresponding PV cell.

18. The concentrating PV device according to claim 16, wherein, for each concentrating lens, the plurality of microlenses are configured to produce a homogenized distribution of the superimposed plurality of beamlets on the corresponding PV cell.

19. A method of forming an optical element, the method comprising:
selecting at least two different wavelengths within a wavelength band;
determining a Fresnel lens height to maximize a diffraction efficiency of the selected different wavelengths; and
forming, on a surface of a transparent material, at least one Fresnel lens with the Fresnel lens height.

20. The method according to claim 19, the determining of the Fresnel lens height including:
for each selected wavelength, determining a deviation from a maximum phase retardation;
minimizing an error in the deviation for all of the selected wavelengths; and
selecting a minima from the minimized error as the Fresnel lens height.

21. The method according to claim 19, the determining of the Fresnel lens height including:
modeling a square error function (SE) representing a sum of a square error of a deviation from a maximum phase retardation for all of the selected wavelengths, the square error function (SE) being:
$$SE ( d ) = {\sum }_{i = 1}^{N} {( min ( {φ}_{F} ( d , {λ}_{i} ) , 2 π - {φ}_{F} ( d , {λ}_{i} ) ) )}^{2}$$
where λᵢ represents one of the selected wavelengths, d represents a non-optimized Fresnel lens height, N represents a total number of selected wavelengths, min represents a minimum and φ_{F} represents a phase retardation of the respective selected wavelength;
applying all of the selected wavelengths to the square error (SE) function to produce at least one minima; and
selecting the Fresnel lens height from among the at least one minima.

22. The method according to claim 19, further including:
forming a plurality of microlenses for each Fresnel lens on a further surface of the transparent material opposite the surface including the Fresnel lens.

23. The method according to claim 19, further including:
for each Fresnel lens, forming the surface as a refractive surface.

24. The method according to claim 19, wherein the at least two different wavelengths are selected to correspond to one or more wavelength absorption bands of a photovoltaic (PV) cell.
